(19) United States
(12) Patent Application Publication
(10) Pub. No.: US 2013/0114634 A1
(43) Pub. Date: May 9, 2013

(54) DBR Laser Diode With Periodically Modulated Grating Phase

(71) Applicants: Dmitri Vladislavovich Kuksenkov, Big Flats, NY (US); Dragan Pikula, Horseheads, NY (US); Rostislav Vatchev Roussev, Painted Post, NY (US)

(72) Inventors: Dmitri Vladislavovich Kuksenkov, Big Flats, NY (US); Dragan Pikula, Horseheads, NY (US); Rostislav Vatchev Roussev, Painted Post, NY (US)

(21) Appl. No.: 13/292,479

(22) Filed: Nov. 9, 2011

(51) Int. Cl. H01S 5/125

(52) U.S. Cl. 372/45.01

(57) ABSTRACT

A DBR laser diode is provided where the phase φ of the wavelength selective grating is characterized by periodic phase jumps of period Λ_{PM} and modulation depth φ_{J} and the phase jumps of the wavelength selective grating are arranged substantially symmetrically, antisymmetrically, or asymmetrically about a midpoint of the DBR section along an optical axis of the DBR laser diode. Length of the wavelength selective grating along the optical axis of propagation of the DBR laser diode is (i) between approximately (m+0.01)Λ_{PM} and approximately (m+0.49)Λ_{PM}, when the phase distribution is substantially symmetric with respect to the midpoint of the DBR section, (ii) between approximately (m−0.49)Λ_{PM} and approximately (m−0.01)Λ_{PM} when the phase distribution is substantially antisymmetric with respect to the midpoint of the DBR section, and (iii) between approximately (m+0.6)Λ_{PM} and approximately (m+0.9)Λ_{PM} when the phase distribution is substantially asymmetric with respect to the midpoint of the DBR section.

### BACKGROUND

The present disclosure relates to laser diodes characterized by multi-wavelength emission and, more particularly, to distributed Bragg reflector (DBR) laser diodes where the wavelength selective grating of the laser diode generates reflections at multiple wavelengths simultaneously. The resulting laser output spectrum includes signals at multiple wavelengths. The present disclosure also relates to the use of a multi-wavelength laser diodes as a pump source for frequency up-conversion through second-harmonic (SHG) and sum-frequency (SFG) generation, as can be applied for conversion of an IR pump to emission in the green portion of the optical spectrum for example.

### BRIEF SUMMARY

Concepts of the present disclosure are particularly well-suited for speckle-reduced synthetic laser sources emitting, for example, in the green portion of the optical spectrum because, to reduce speckle, laser sources preferably emit several wavelengths simultaneously and may utilize a SHG, SFG, or other type of wavelength conversion device with multiple phase-matching conversion peaks. The present inventors have recognized that when a DBR pump laser is operated in relatively short-pulsed regime, all wavelengths substantially reflected by the wavelength selective grating of the DBR laser are generated simultaneously in the laser output spectrum. Accordingly, the ideal grating for the pump laser should reflect only the desired predetermined small number of pump wavelengths that can be frequency up-converted through SHG or SFG utilizing the available phasematching peaks of the wavelength conversion device. Lasing at other pump wavelengths is seen as parasitic and can reduce overall efficiency of the device since these additional pump wavelengths do not participate in the frequency up-conversion process. For many useful projection surfaces, up-converted output wavelengths are preferably separated by about 0.4 nm or more to allow speckle reduction via the addition of uncorrelated speckle patterns. For example, if two pump IR wavelengths λ₁ and λ₂ produce three green output wavelengths 0.5 λ₁, 0.5 λ₂, and 0.5(λ₁+λ₂), via SHG and SFG, the two pump wavelengths should be separated by more than about 1.6 nm, so that the three green output wavelengths can be separated by more than about 0.4 nm.

Referring initially to FIG. 1, the general structure of a DBR laser diode 10 with wavelength selective output consists of at least two sections, a DBR section 12 with a wavelength selective grating and a gain section 14. Very often, a phase section 16 is also provided. FIG. 1 also illustrates a wavelength conversion device 20 schematically. The wavelength conversion device 20 is characterized by multiple phase-matching conversion peaks designed to enable the frequency up-conversion of the reflectivity peaks of the wavelength selective grating of the DBR section 12 in the form of SHG and SFG. Collectively, the laser 10 and the wavelength conversion device 20 form a frequency up-converted synthetic laser source. Beyond the details of the wavelength selective grating of the DBR section 12 disclosed herein, the specific manner of construction of the laser 10 and the wavelength conversion device 20 are beyond the scope of the present disclosure and can be readily gleaned from a variety of teachings on the subject. For example, it is contemplated that SHG devices with 3-peak and 5-peak quasi-phasematching (QPM) wavelength response can be utilized with multi-peak-spectrum DBR sections within the scope of the present disclosure.

Generally, the device length of the laser 10 will be limited. In practice most of the device length is typically allocated to gain section 14 of the laser 10 and the length of the DBR section 12 is often limited to approximately 700 μm. The present inventors recognize that the grating of the DBR section 12 should be designed to exhibit high reflectivity at two or three desired pump (IR) wavelengths, separated preferably by more than about 1.6 nm. Further, the reflectivity of the DBR section 12 at other wavelengths should be as small as possible to avoid efficiency reduction due to generation of unused IR light. In many cases, the respective reflectivities of individual peaks of the grating should be approximately equal to allow stable operation of the pump laser simultaneously at all desired wavelengths over a wide range of pump power levels. In some embodiments, the respective reflectivities of individual peaks of the grating are tailored to compensate for existing slope in the gain spectrum of the laser. In some embodiments involving DBR grating with 3-peak wavelength response, the optimum magnitude of the central peak may be smaller than the magnitudes of the two outer peak for facilitating maximum speckle reduction when combined with an SHG-device with 5-peak QPM-response spectrum. The present inventors have recognized that an optimum range of ratios of the three peaks of the DBR response for speckle-reduction applications is between about 2:1:2 and about 1:1.5:1.

In accordance with one embodiment of the present disclosure, a DBR laser diode is provided where the phase φ of the wavelength selective grating is characterized by periodic phase jumps of period Λ_{PM} and modulation depth φ_{J} and the phase jumps of the wavelength selective grating are arranged substantially symmetrically, antisymmetrically, or asymmetrically about a midpoint of the DBR section along an optical axis of the DBR laser diode. The length of the wavelength selective grating along the optical axis of propagation of the DBR laser diode is (i) between approximately (m+0.01)Λ_{PM} and approximately (m+0.49)Λ_{PM}, when the phase distribution is substantially symmetric with respect to the midpoint of the DBR section, (ii) between approximately (m−0.49)Λ_{PM} and approximately (m−0.01)Λ_{PM} when the phase distribution is substantially antisymmetric with respect to the midpoint of the DBR section, and (iii) between approximately (m+0.6)Λ_{PM} and approximately (m+0.9)Λ_{PM} when the phase distribution is substantially asymmetric with respect to the midpoint of the DBR section. The modulation depth φ_{J} is preferably between approximately 0.727 and approximately 1.147.

### BRIEF DESCRIPTION OF THE SEVERAL VIEWS OF THE DRAWINGS

The following detailed description of specific embodiments of the present disclosure can be best understood when read in conjunction with the following drawings, where like structure is indicated with like reference numerals and in which:

FIG. 1 is a schematic illustration of a frequency up-converted synthetic laser source;

FIG. 2 is a phase modulation diagram illustrating the spatial distribution of the distinct phase portions of a phase-symmetric wavelength selective grating according to the present disclosure;

FIG. 3 illustrates the reflectivity peaks typically associated with the phase-symmetric wavelength selective grating of FIG. 2;

FIG. 4 is a phase modulation diagram illustrating the spatial distribution of the distinct phase portions of a phase-asymmetric wavelength selective grating according to the present disclosure;

FIG. 5 illustrates the reflectivity peaks typically associated with the phase-asymmetric wavelength selective grating of FIG. 4;

FIG. 6 is a phase modulation diagram illustrating the properties of an alternative phase-asymmetric wavelength selective grating according to the present disclosure;

FIG. 7 illustrates the reflectivity peaks typically associated with the alternative phase-asymmetric wavelength selective grating of FIG. 6;

FIG. 8 is a phase modulation diagram illustrating the spatial distribution of the distinct phase portions of a trapezoidal-phase wavelength selective grating according to the present disclosure;

FIG. 9 illustrates the reflectivity peaks typically associated with the trapezoidal-phase wavelength selective grating of FIG. 8; and

FIG. 10 is a phase modulation diagram illustrating the spatial distribution of the distinct phase portions of a phase-antisymmetric wavelength selective grating according to the present disclosure.

### DETAILED DESCRIPTION

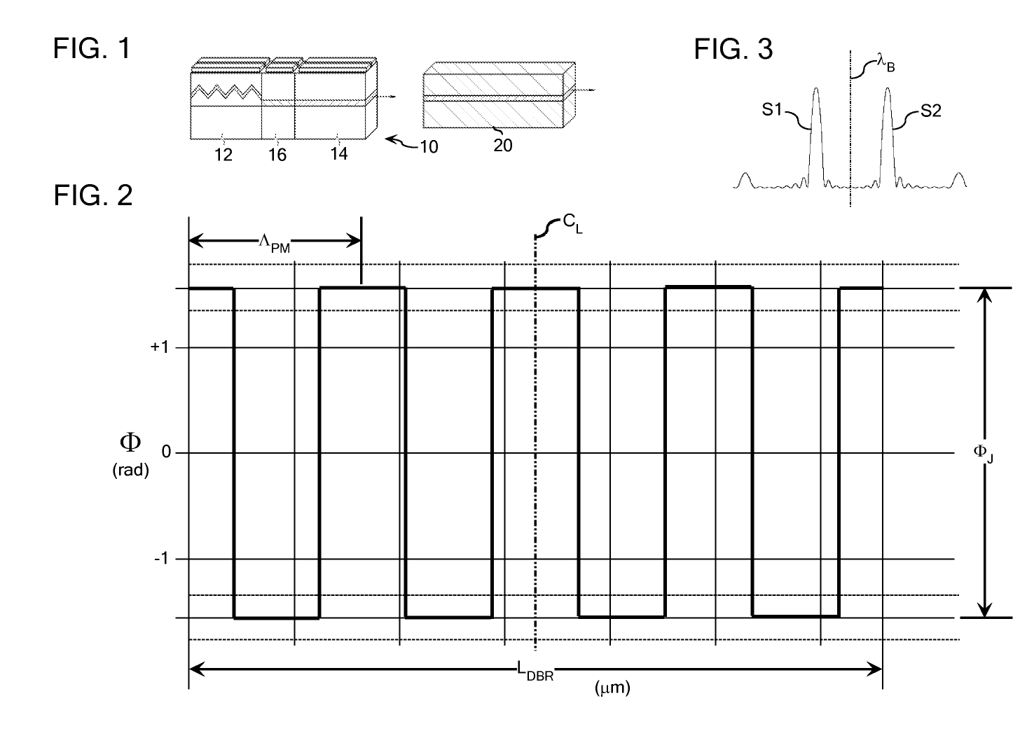

As is noted above, the DBR laser diode 10 illustrated in FIG. 1 comprises a DBR section comprising a wavelength selective grating. The specific configuration of one type of wavelength selective grating according to the present disclosure is illustrated in the phase-distribution diagram of FIG. 2. More specifically, as is illustrated in FIG. 2, the wavelength selective grating is characterized by a Bragg wavelength λ_{B} and a periodically modulated grating phase φ.

As will be appreciated by those familiar with DBR lasers, a DBR section of a DBR laser comprises a Bragg mirror, i.e., a wavelength-selective light-reflecting device based on Bragg reflection at a periodic structure. The periodicity of the structure of the DBR section defines the Bragg wavelength λ_{B} of the laser as follows

λ_{B}=2n_{eff}λ/m_{d}

where Λ is the fundamental period of the Bragg grating, n_{eff} is the effective refractive index of the guided mode in the region of the grating, and m_{d} is the diffraction order. In one example, a DBR laser using GaAs as the grating and gain medium, the grating period for a first-order grating with m_{d}=1 is about 159 nm for a Bragg wavelength of about 1062 nm.

The phase φ of the wavelength selective grating is characterized by periodic phase jumps of period Λ_{PM} and modulation depth φ_{J} that are designed to generate two or more reflectivity peaks in the form of sidebands S1, S2 about the central Bragg wavelength Λ_{B} of the grating, as is illustrated in FIG. 3. More specifically, when periodic phase modulation of this nature is used, the period of phase modulation required to obtain side-bands in the reflectivity shifted by Δλ in wavelength from the central reflectivity peak is as follows

$${Λ}_{PM} = \frac{1}{2 {N}_{eff}^{g}} \frac{{λ}_{B}^{2}}{Δ λ}$$

where λ_{B} is the Bragg wavelength attributable to a non-modulated grating, i.e., the center wavelength of the reflection spectrum of the modulated grating, and N^{g}_{eff} is the group effective index of the laser waveguide optical mode in the region of the grating. For example, and not by way of limitation, it is contemplated that the phase modulation period Λ_{PM} of the wavelength selective grating can be between approximately 20 μm and approximately 200 μm. These phase modulations can be obtained in practice by longitudinally shifting discrete sections of the grating by a distance φΛ/2π, where φ is the required phase shift and Λ is the fundamental period of the unperturbed grating. Methods to achieve this are well documented in the art and include, for example, using e-beam lithography with the shifts incorporated into the lithography patterns. In some cases when an even number of major reflectivity peaks is pursued, the central peak at wavelength λ_{B} is substantially suppressed, and the period of phase modulation is selected at twice the value prescribed by the aforementioned equation, to result in peak spacing of Δλ. E.g., for obtaining an even number of peaks spaced by Δλ, with suppressed central peak at λ=λ_{B}, the period of phase modulation may be selected as

$${Λ}_{PM} = \frac{1}{{N}_{eff}^{g}} \frac{{λ}_{B}^{2}}{Δ λ}$$

The length L_{DBR} of the wavelength selective grating along the optical axis of propagation of the DBR laser diode 10 is also illustrated in FIG. 3. Preferably, the length L_{DBR} is specified in ranges in terms of an integer m and the period of phase modulation Λ_{PM} of the wavelength selective grating, depending on whether the phase modulation distribution is symmetric, antisymmetric, or asymmetric.

Standard Symmetry. When the phase jumps of the wavelength selective grating are arranged about a midpoint of the DBR section in such a way that the graphical representation of the phase distribution is substantially symmetric with respect to the same midpoint of the DBR section, the length of the wavelength selective grating is suitably between approximately (m+0.01)Λ_{PM} and approximately (m+0.49)Λ_{PM}, and, in many cases, more preferably between (m+0.1)Λ_{PM} and approximately (m+0.4)Λ_{PM} or between approximately (m+0.15)Λ_{PM} and approximately (m+0.35)Λ_{PM}. It should be understood that these ranges of suitable lengths are also applicable for substantially-symmetric phase modulation cases where the phase distribution can be represented as originally symmetric phase distribution that has been longitudinally shifted along the optical axis by up to 15% of the period of phase modulation, or where the phase distribution can be represented as originally a symmetric phase distribution that has been then truncated on one or both sides in such a way that up to 15% of a period of phase modulation has been removed from or added to the total optimum length of phase modulation. Such cases can often be observed in practice, for example, when cleaving of the DBR laser occurs in a somewhat random fashion, leading to variation of the beginning of end of the DBR grating compared to the designed beginning or end. These types of limited deviations from truly symmetric phase modulation formats should be considered within the scope of the substantially symmetric embodiments described herein.

Anti-symmetry. In antisymmetric configurations, the segment lengths of each phase segment on opposite sides of the midpoint C_{L} of the DBR section 12 are equal but the phase values associated with each segment are equal and opposite in sign. For example, in the embodiment illustrated in FIG. 10, the phase values associated with each segment are shifted by approximately +/−π, on opposite sides of the midpoint C_{L}, taking on equal in magnitude and opposite in sign phase values of approximately +π/2 and −π/2. In addition, for anti-symmetric configurations, the midpoint C_{L} of the DBR grating is aligned with a central phase jump, as opposed to being aligned with the midpoint of the central phase segment. When near-π shifts are considered, they may assume a value between about 0.8π and 1.22π, or a value differing from that by an integer multiple of 2π, including negative values. In one embodiment with strongly suppressed central peak at the Bragg wavelength, the phase jumps are equal to a positive or negative odd-integer multiple of π. When the phase jumps of the wavelength selective grating are arranged anti-symmetrically about a midpoint of the DBR section, which is described below with reference to FIG. 10, the length of the wavelength selective grating is suitably between approximately (m−0.49)Λ_{PM} and approximately (m−0.01)Λ_{PM}, which is the functional equivalent of (m+0.51)Λ_{PM} to (m+0.99)Λ_{PM}, and, in many cases, more preferably between approximately (m−0.4)Λ_{PM} and approximately (m−0.1)Λ_{PM}.

Asymmetry. When the phase jumps of the wavelength selective grating are arranged asymmetrically about a midpoint of the DBR section, the length of the wavelength selective grating is suitably between approximately (m+0.6)Λ_{PM} and approximately (m+0.9)Λ_{PM} and, in many cases, more preferably between approximately (m+0.7)Λ_{PM} and approximately (m+0.8)Λ_{PM}.

Although typical DBR lasers are of limited length, the DBR section 12 of the laser diode 10 is effective at relatively limited lengths, i.e., lengths between approximately 600 μm and approximately 750 μm. More specifically, given the above-noted range for the length L_{DBR} it is contemplated that the integer m may be as low as 1 and as high as 10, noting that smaller values of m will be more likely to result in improved performance in terms of overall efficiency and suppression of parasitic spectral peaks. In some embodiments, it is contemplated that m will be 2, 3, 4, or 5. Effective wavelength selective gratings can be configured where the length L_{DBR} is less than approximately 700 μm and the positive integer m is ≦8. In other embodiments, the length of the wavelength selective grating can be restricted to be approximately (m+0.2)Λ_{PM}. One optimum configuration, for a GaAs DBR laser diode, utilizes a grating length of 4.2Λ_{PM} and a phase modulation period of 158.645 μm, which yields a sideband separation of approximately 2 nm and a grating length of 666 μm. A longer grating length in this case would increase the magnitude of the desirable sidebands. In some embodiments, particularly those with first-order DBR gratings, the grating length may be between (m+0.01)Λ_{PM} and (m +0.49)Λ_{PM}, where m=2 and the spacing of the two reflectance sidebands is adequate to meet the requirements of speckle reduction, for example. The reflectivity of the main sidebands S1 and S2 can be maximized by optimizing the ratio between grating length and the phase modulation period to suppress unwanted higher-order sidebands.

FIG. 2 also illustrates the phase modulation depth φ_{J} that defines the periodic phase modulation. It is contemplated that the depth of phase modulation may fall between approximately 0.72π and approximately 1.14π or, more particularly, between approximately 0.88π and approximately 1.12π, although these parameters can be varied according to specific applications of the technology disclosed herein. For example, for trapezoidal modulation targeting a 3-peak distribution. depths smaller than 0.86π, e.g., between approximately 0.72π and 0.86π, are typically required, while two-peak spectra work well between approximately 0.86π and approximately 1.14π.

As is illustrated in FIG. 3, the Bragg wavelength λ_{B}, the period Λ_{PM} and modulation depth φ_{J} of the phase jumps, and the length of the wavelength selective grating are such that the wavelength selective grating exhibits two dominant reflectivity peaks, i.e., peaks with reflectance maxima at least 5 times larger than all other reflectivity peaks attributable to the wavelength selective grating. In a majority of cases the dominant peaks are at least 5 times larger than any other reflectivity peaks attributable to the wavelength selective grating. In addition, it is noted that these two dominant reflectivity peaks can be separated by at least about 1.6 nm, meeting the requirements of the frequency up-converted laser sources discussed above. In addition, although not required, it is noted that the respective maxima of the two dominant reflectivity peaks are approximately equal.

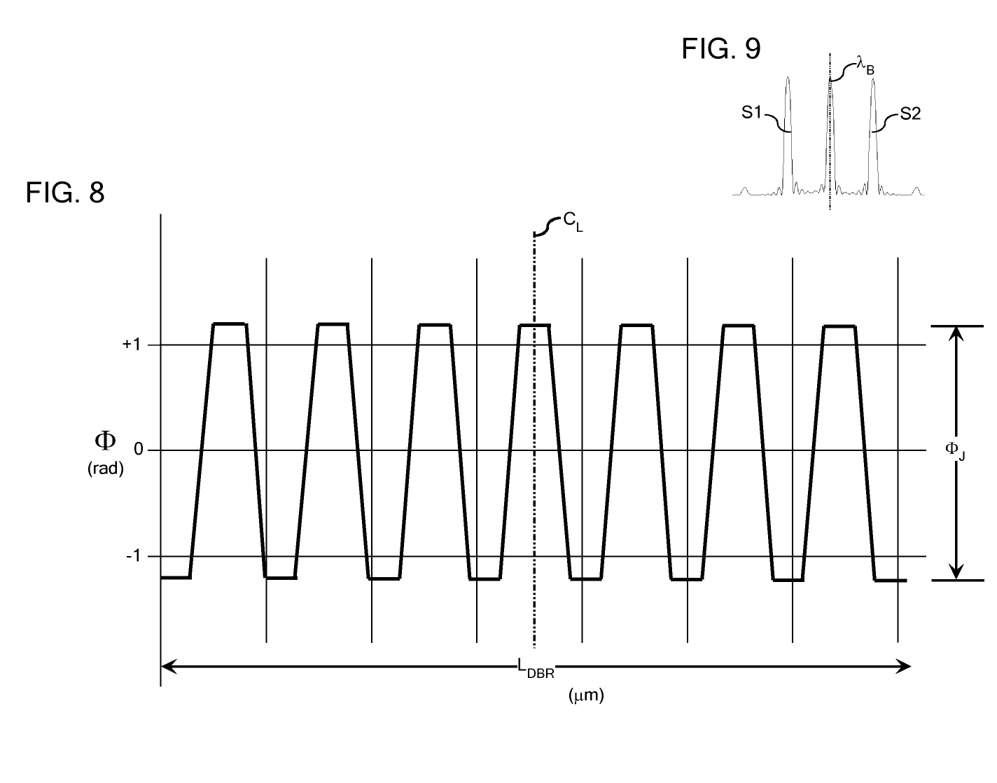

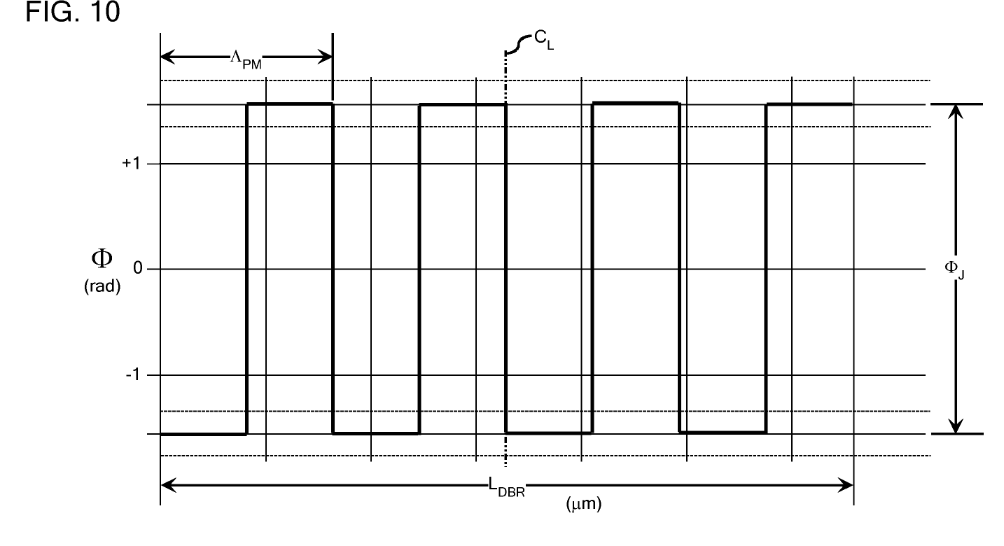

In one embodiment, referring to FIG. 8, the phase jumps of the wavelength selective grating are presented in the form of linear phase ramps, resulting in a substantially trapezoidal periodic phase distribution. As a result, the Bragg wavelength λ_{B}, the period Λ_{PM} and modulation depth φ_{J} of the phase, and the length of the wavelength selective grating form a wavelength selective grating that exhibits three dominant reflectivity peaks (see FIG. 9). Generally, a trapezoidal phase modulation allows better side band suppression ratio (SBSR) by substantially suppressing the parasitic peaks outside the frequency range of the three main peaks. In one embodiment, the trapezoidal profile period is 94.4 um and the plateau duty cycle (PDC), i.e., the ratio of the flat portion of the trapezoidal phase half-period to the half-period itself, is 65%. The depth of phase modulation is 0.714π. Optimal length is in the range between approximately 7.2 periods and approximately 7.35 periods. In another example, characterized by three approximately equal peaks and an SBSR of 9.7 dB in a low reflectivity regime, the PDC is 40% and the depth of modulation is 0.816π. In another embodiment, the PDC is 0.45, the depth of modulation is 0.79π, and the SBSR in the low-reflectivity regime is about 10.5 dB. The SBSR is about 10.2 dB when the PDC is 0.43 and the depth of modulation is 0.80π. Hence, with trapezoidal phase modulation, improvement of SBSR over the rectangular phase modulation can be obtained when the plateau duty cycle is greater than about 0.43. SBSR values comparable to best-case scenarios for rectangular phase modulation can be obtained when the PDC is in the range from about 0.40 to about 0.43. As before, optimum truncation is obtained when the periodic modulation waveform is symmetric with respect to the center of the DBR grating, and the length of the DBR grating is in the range from about (m+0.01)Λ_{PM} to about (m+0.49)Λ_{PM}, preferably between (m+0.1)Λ_{PM} and (m+0.4)Λ_{PM}.

The embodiments of FIGS. 2 and 8 represent the implementation of symmetric periodic phase modulation. More specifically, the periodic phase jumps, which may, in some cases, be represented as ramps of opposite character, e.g., “up” or “down” ramps, are arranged symmetrically about the midpoint C_{L} of the DBR section 12 along the optical axis of the DBR laser diode 10, such that the graphical representation of the phase distribution appears symmetric with respect to the midpoint C_{L}. It is contemplated that although the phase jumps are substantially vertical in some of the illustrated embodiments, the jumps may also comprise inclined or curved jumps, i.e., ramps.

Although not required, the period Λ_{PM} and modulation depth φ_{J} of the phase jumps do not vary along the optical axis of the DBR laser diode. It is contemplated, however, that the modulation depth φ_{J} of the phase jumps may vary along the optical axis of the DBR laser diode by as much as approximately 0.15π. In addition, the period of phase modulation may vary up to approximately 25%, which would result in some broadening of the reflection peaks which may be desirable in some cases. A symmetric periodic phase modulation in the form of periodic phase jumps can be mathematically described with the phase distribution formula

$$Φ ( x ) = \pm 0.5 {Φ}_{J} sign [ cos ( \frac{2 π x}{{Λ}_{PM}} ) ]$$

Symmetric trapezoidal phase modulation is similar, except that the jumps are presented in the form of ramps, and the constant-phase regions are shortened symmetrically to plateaus characterized by a plateau duty cycle. The plateau duty cycle may vary between the extreme cases of 0 (triangular phase distribution) and 1 (rectangular phase distribution, as in FIG. 2). In symmetric phase distributions, the center of the DBR structure occurs in the middle of a segment of constant phase.

Similarly, an antisymmetric periodic phase modulation can be mathematically described with the phase distribution formula

$$Φ ( x ) = \pm 0.5 {Φ}_{J} sign [ sin ( \frac{2 π x}{{Λ}_{PM}} ) ] .$$

A trapezoidal antisymmetric phase distribution can be obtained from the above phase-jump sequence by replacing the phase jumps with ramps and shortening correspondingly the constant-phase segments in accordance with a prescribed plateau duty cycle. For antisymmetric phase distributions, discussed in further detail below with reference to FIG. 10, a phase jump or the middle of a phase ramp occurs at the middle of the DBR-grating length.

FIG. 10 illustrates an antisymmetric phase distribution according to one embodiment of the present disclosure. It is contemplated that embodiments utilizing antisymmetric periodic phase modulation may employ periodic phase jumps according to the aforementioned formula, where, for example, the depth of modulation φ_{J} is approximately equal to π radians, and the length of the DBR grating is between (m+0.51)Λ_{PM} and (m+0.99)Λ_{PM}, where m is a positive integer, preferably between 1 and 5. These embodiments are likely to produce a reflection spectrum with two pronounced peaks disposed symmetrically on the two sides of a substantially suppressed peak at λ_{B}, and relatively small parasitic side peaks. The resulting SBSR will be relatively high, i.e., similar to that achievable with symmetric periodic phase distribution with DBR grating length ranging from about (m+0.01)Λ_{PM} to about (m+0.49)Λ_{PM}.

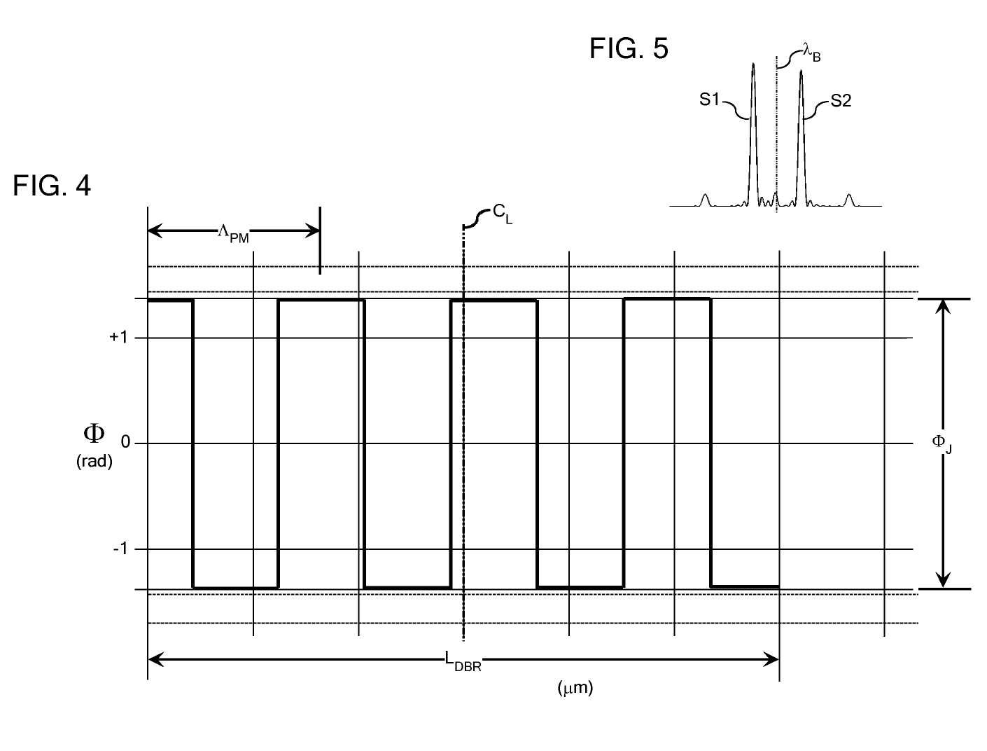

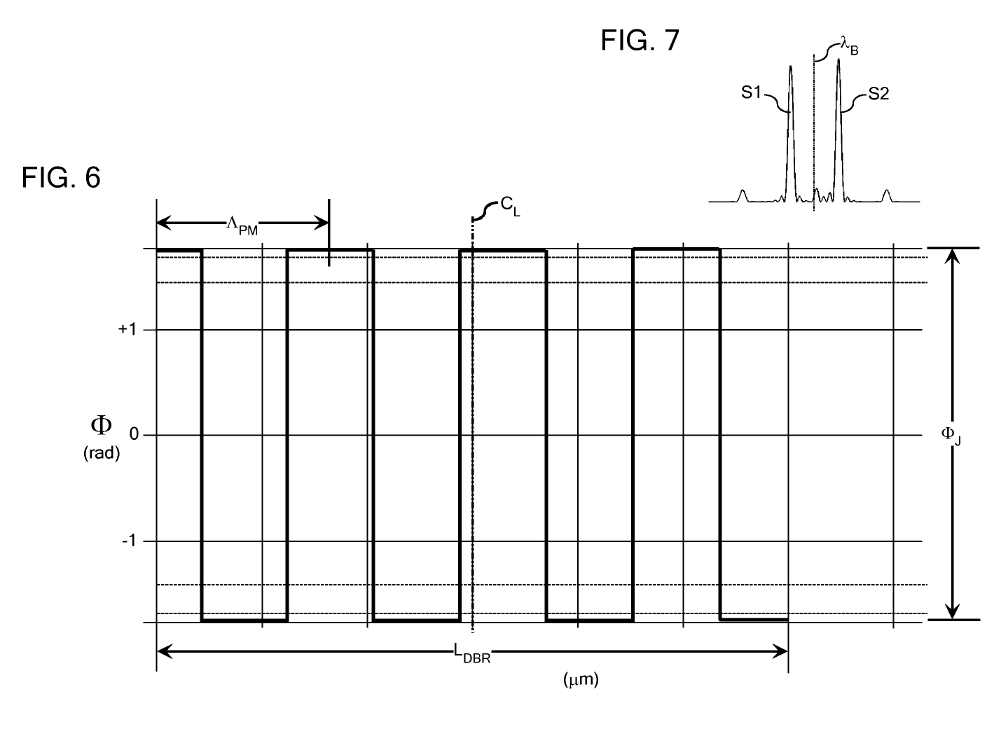

The embodiments of FIGS. 4 and 6 represent an implementation of asymmetric periodic phase modulation and the use of this asymmetry to compensate for any gain slope in the laser diode 10. Specifically, referring to FIGS. 4 and 6, the phase jumps of the wavelength selective grating are arranged asymmetrically about the midpoint C_{L} of the DBR section along the optical axis of the DBR laser diode. To maintain the parasitic peaks low in asymmetric embodiments, the modulation depth φ_{J} of the phase jumps should be between approximately 0.92π and approximately 1.08π or, more specifically, between approximately 0.96π and approximately 1.04π. As is explained in further detail below, the two major peaks in the reflectivity spectrum differ in magnitude when the modulation depth φ_{J} of the phase jumps is somewhat different from π. The antisymmetric periodic phase modulation described above with respect to FIG. 10 can also be arranged to result in two pronounced reflectivity peaks with unequal magnitude, particularly when the modulation depth φ_{J} is in the range between about 0.92π and about 1.08π, although somewhat different from exactly π.

As is illustrated in FIGS. 5 and 7, the asymmetric gratings of FIGS. 4 and 6 can be tailored to exhibit two dominant reflectivity peaks S1, S2 with different magnitudes. In FIG. 4, the modulation depth φ_{J} of the periodic phase jump is slightly smaller than π and, as such, generates a relatively low reflectivity peak S2 at longer wavelengths (see FIG. 5). In contrast, referring to FIG. 6, when the modulation depth φ_{J} is slightly larger than 7, the grating generates a relatively low reflectivity peak S1 at shorter wavelengths (see FIG. 7). This phenomenon can be used to at least partially compensate for any slope in the gain spectrum of the DBR laser diode. More specifically, in both cases, the modulation depth φ_{J} of the phase jumps is selected to yield a magnitude difference between respective maxima of the two dominant reflectivity peaks S1, S2.

Alternatively, the relative magnitudes of the two reflectance peaks can be changed by shifting the phase profile with respect to the device center, i.e., along the x-axis of the phase diagrams illustrated in FIGS. 2, 4, 6 and 8. A difference in magnitude between the two dominant reflectivity peaks S1, S2 can be tailored to define a reflectivity slope with a magnitude that is approximately equivalent to the magnitude of the laser gain slope but has an opposite sign. The result is a laser diode where he two actual output lasing peaks are equal even though there is a slope in the gain spectrum of the laser. It is noted that the ratio of the peaks S1 and S2 can be changed within limits and that, generally, the fewer the periods of phase modulation in the DBR grating length, the larger the range of ratios of the two peaks.

It is noted that terms like “preferably,” “commonly,” and “typically,” when utilized herein, are not utilized to limit the scope of the claimed invention or to imply that certain features are critical, essential, or even important to the structure or function of the claimed invention. Rather, these terms are merely intended to identify particular aspects of an embodiment of the present disclosure or to emphasize alternative or additional features that may or may not be utilized in a particular embodiment of the present disclosure.

For the purposes of describing and defining the present invention it is noted that the terms “substantially” and “approximately” are utilized herein to represent the inherent degree of uncertainty that may be attributed to any quantitative comparison, value, measurement, or other representation. The terms “substantially” and “approximately” are also utilized herein to represent the degree by which a quantitative representation may vary from a stated reference without resulting in a change in the basic function of the subject matter at issue.

Having described the subject matter of the present disclosure in detail and by reference to specific embodiments thereof, it is noted that the various details disclosed herein should not be taken to imply that these details relate to elements that are essential components of the various embodiments described herein, even in cases where a particular element is illustrated in each of the drawings that accompany the present description. Rather, the claims appended hereto should be taken as the sole representation of the breadth of the present disclosure and the corresponding scope of the various inventions described herein. Further, it will be apparent that modifications and variations are possible without departing from the scope of the invention defined in the appended claims. More specifically, although some aspects of the present disclosure are identified herein as preferred or particularly advantageous, it is contemplated that the present disclosure is not necessarily limited to these aspects.

It is noted that one or more of the following claims utilize the term “wherein” as a transitional phrase. For the purposes of defining the present invention, it is noted that this term is introduced in the claims as an open-ended transitional phrase that is used to introduce a recitation of a series of characteristics of the structure and should be interpreted in like manner as the more commonly used open-ended preamble term “comprising.”

1. A DBR laser diode comprising a DBR section and a gain section, wherein:
the DBR section comprises a wavelength selective grating;
the wavelength selective grating is characterized by a periodically modulated grating phase φ and a Bragg wavelength λ_{B};
the phase φ of the wavelength selective grating is characterized by periodic phase jumps of period Λ_{PM} and modulation depth φ_{J};
the phase jumps of the wavelength selective grating are arranged substantially symmetrically, antisymmetrically, or asymmetrically about a midpoint of the DBR section along an optical axis of the DBR laser diode;
a length of the wavelength selective grating along the optical axis of propagation of the DBR laser diode is
between approximately (m+0.01)Λ_{PM} and approximately (m+0.49)Λ_{PM}, when the phase distribution is substantially symmetric with respect to the midpoint of the DBR section,
between approximately (m−0.49)Λ_{PM} and approximately (m−0.01)Λ_{PM} when the phase distribution is substantially antisymmetric with respect to the midpoint of the DBR section, and
between approximately (m+0.6)Λ_{PM} and approximately (m+0.9)Λ_{PM} when the phase distribution is substantially asymmetric with respect to the midpoint of the DBR section,
where m is a positive integer and Λ_{PM} is the phase modulation period of the wavelength selective grating; and
the modulation depth φ_{J} is between approximately 0.72π and approximately 1.14π.

2. A DBR laser diode as claimed in claim 1 wherein the Bragg wavelength λ_{B}, the period Λ_{PM} and modulation depth φ_{J} of the phase jumps, and the length of the wavelength selective grating are such that the wavelength selective grating exhibits 2-5 dominant reflectivity peaks.

3. A DBR laser diode as claimed in claim 2 wherein the two dominant reflectivity peaks closest to the Bragg wavelength λ_{B} are separated by at least about 1.6 nm.

4. A DBR laser diode as claimed in claim 1 wherein:
the phase distribution of the wavelength selective grating is characterized by a substantially trapezoidal periodic phase waveform; and
the Bragg wavelength λ_{B}, the period Λ_{PM} and modulation depth φ_{J} of the periodic phase waveform, and the length of the wavelength selective grating are such that the wavelength selective grating exhibits at least three dominant reflectivity peaks.

5. A DBR laser diode as claimed in claim 1 wherein the phase distribution of the wavelength selective grating is symmetric with respect to a midpoint of the DBR section along the optical axis of the DBR laser diode.

6. A DBR laser diode as claimed in claim 5 wherein the period Λ_{PM} and modulation depth φ_{J} of the phase jumps do not vary along the optical axis of the DBR laser diode.

7. A DBR laser diode as claimed in claim 5 wherein the modulation depth φ_{J} of the phase jumps varies along the optical axis of the DBR laser diode by less than approximately 0.15π, the period of phase modulation varies along the optical axis of the DBR laser diode by up to approximately 25%, or both.

8. A DBR laser diode as claimed in claim 1, wherein:
the phase distribution of the wavelength selective grating is symmetric with respect to a midpoint of the DBR section along the optical axis of the DBR laser diode; and
the length of the wavelength selective grating along an optical axis of propagation of the DBR laser diode is between approximately (m+0.1)Λ_{PM} and approximately (m+0.4)Λ_{PM}.

9. A DBR laser diode as claimed in claim 1 wherein:
the phase distribution of the wavelength selective grating is asymmetric with respect to a midpoint of the DBR section along the optical axis of the DBR laser diode; and
the length of the wavelength selective grating along an optical axis of propagation of the DBR laser diode is between approximately (m+0.6)Λ_{PM} and approximately (m+0.9)Λ_{PM}.

10. A DBR laser diode as claimed in claim 9 wherein:
the phase distribution of the wavelength selective grating is asymmetric with respect to a midpoint of the DBR section along the optical axis of the DBR laser diode.
the DBR laser diode is characterized by a wavelength-dependent gain;
the wavelength selective grating exhibits a plurality of dominant reflectivity peaks in the form of sidebands about a central Bragg wavelength λ_{B} of the grating;
the modulation depth φ_{J} of the phase jumps is selected to yield a magnitude difference between reflectivity peak maxima on opposite sides of the central Bragg wavelength λ_{B}; and
the difference in magnitude between the reflectivity peaks partially or entirely compensates for the slope of the wavelength-dependent gain of the DBR laser diode.

11. A DBR laser diode as claimed in claim 10 wherein the magnitude difference between respective maxima of the two dominant reflectivity peaks defines a reflectivity slope having a magnitude that is approximately equivalent to the magnitude of the gain slope but opposite in sign.

12. A DBR laser diode as claimed in claim 1 wherein:
the phase distribution of the wavelength selective grating is antisymmetric with respect to the midpoint of the DBR section along the optical axis of the DBR laser diode; and
the length of the wavelength selective grating along an optical axis of propagation of the DBR laser diode is between approximately (m−0.49)Λ_{PM} and approximately (m−0.01)Λ_{PM}.

13. A DBR laser diode as claimed in claim 1 wherein the phase modulation of the wavelength selective grating is characterized by a substantially rectangular or substantially trapezoidal periodic phase distribution.

14. A DBR laser diode as claimed in claim 1 wherein the length of the wavelength selective grating is between approximately 600 μm and approximately 750 μm.

15. A DBR laser diode as claimed in claim 1 wherein 1≦m≦10.

16. A DBR laser diode as claimed in claim 1 wherein:
the length of the wavelength selective grating is less than approximately 700 μm; and
the positive integer m is ≦8.

17. A DBR laser diode as claimed in claim 15 wherein the length of the wavelength selective grating is between approximately (m+0.15)Λ_{PM} and (m-F0.35)Λ_{PM}.

18. A DBR laser diode as claimed in claim 1 wherein the modulation depth φ_{J} is between approximately 0.88π and approximately 1.12π.

19. A DBR laser diode as claimed in claim 1 wherein:
the DBR laser diode is combined with a wavelength conversion device to form a frequency up-converted synthetic laser source; and
the wavelength conversion device is characterized by multiple phase-matching conversion peaks designed to frequency up-convert the reflectivity peaks of the wavelength selective grating of the DBR section through second harmonic generation or sum-frequency generation, or both.

20. A DBR laser diode comprising a DBR section and a gain section, wherein:
the DBR section comprises a wavelength selective grating;
the wavelength selective grating is characterized by a periodically modulated grating phase φ and a Bragg wavelength λ_{B};
the phase φ of the wavelength selective grating is characterized by periodic phase jumps of period Λ_{PM} and modulation depth φ_{J};
the phase jumps of the wavelength selective grating are arranged symmetrically, anti-symmetrically, or asymmetrically about a midpoint of the DBR section along the optical axis of the DBR laser diode;
a length of the wavelength selective grating along an optical axis of propagation of the DBR laser diode is less than approximately 750 μm and is
between approximately (m+0.01)Λ_{PM} and approximately (m+0.49)Λ_{PM}, when the phase distribution of the wavelength selective grating is symmetric with respect to the midpoint of the DBR section,
between approximately (m−0.49)Λ_{PM} and approximately (m−0.01)Λ_{PM} when the phase distribution of the wavelength selective grating is antisymmetric with respect to the midpoint of the DBR section, and
between approximately (m+0.6)Λ_{PM} and approximately (m+0.9) Λ_{PM} when the phase distribution of the wavelength selective grating is asymmetric with respect to the midpoint of the DBR section,
where m is a positive integer and Λ_{PM} is the phase modulation period of the wavelength selective grating;
the Bragg wavelength λ_{B}, the period Λ_{PM} and modulation depth φ_{J} of the phase jumps, and the length of the wavelength selective grating are such that the wavelength selective grating exhibits a plurality of dominant reflectivity peaks of approximately equal magnitude separated by at least about 1.6 nm.
